(19) United States
(12) Patent Application Publication
(10) Pub. No.: US 2015/0274279 A1
(43) Pub. Date: Oct. 1, 2015

(54) METHOD AND SYSTEM FOR CONTROL INPUT DETECTION

(71) Applicants: Wyatt Logan Sinko, APO, AP (US); Alexander James Matthers, Sag Harbor, NY (US); Lucian James Copeland, Rochester, NY (US); Morgan Walker Sinko, Rochester, NY (US)

(72) Inventors: Wyatt Logan Sinko, APO, AP (US); Alexander James Matthers, Sag Harbor, NY (US); Lucian James Copeland, Rochester, NY (US); Morgan Walker Sinko, Rochester, NY (US)

(21) Appl. No.: 14/673,690

(22) Filed: Mar. 30, 2015

Related U.S. Application Data
(60) Provisional application No. 61/972,468, filed on Mar. 31, 2014.

(51) Int. Cl. B64C 13/10; G01R 19/00; G08G 5/00; B64C 13/12; B64D 10/00

(52) U.S. Cl. CPC B64C 13/10; B64C 13/12; B64D 10/00; G08G 5/0021; G01R 19/0084

(57) ABSTRACT

The Control Input Detection System determines if a crewmember in the Pilot (aft) crew station and/or crewmember in the Co-Pilot Gunner (fore) crew station have/has their hands on the appropriate control surface. A current is routed to each crew station via an Input Analyzer. The current returns a control voltage to the voltmeter. When gloves (or hands) make contact with the control surface, the resistance of the circuit is altered, returning a voltage to the respective control's voltmeter different from the control voltage. The IA will monitor the voltmeters' returns to determine at least one pilot has his hand(s) on the controls. If the control voltage is returned from all four voltmeters, the IA would send a signal a System Processor, for a Display Processor to send an audio tone to the Pilot and CPG's helmets, and an advisory to be displayed on the Enhanced Up-Front Display.

### CROSS REFERENCE TO RELATED APPLICATIONS

This application claims priority from U.S. Patent Application Ser. No. 61/972,468, entitled “System and Method for External Equipment Monitoring t”, filed on 31 Mar. 2014. The benefit under 35 USC §119(e) of the United States provisional application is hereby claimed, and the aforementioned application is hereby incorporated herein by reference.

### FEDERALLY SPONSORED RESEARCH

Not Applicable

### SEQUENCE LISTING OR PROGRAM

Not Applicable

### TECHNICAL FIELD OF THE INVENTION

The present invention relates generally to flight control systems. More specifically, the present invention relates to fully integrated flight control systems in applications where two or more pilots may have control of an aircraft.

### DEFINITIONS

Control Input Detection System, or CIDS is the system of the present invention that is comprised of electronics and integrated into an aircraft such as an Apache helicopter to provide detection of Pilot and Co-Pilot hands on the aircraft controls.

An “input analyzer” or (IA) receives input from the collective voltmeter, cyclic voltmeter or the pilot control station, the co-pilot/gunner control station, and the electronic load center (ELC) aircraft power.

An “OR Gate” returns a positive when either of the inputs is true, or both of the inputs are true.

An “AND Gate” only returns a positive when BOTH inputs are positive, all other cases are negative.

A “NOT Gate” inverts any signal it is input. (i.e. negative=>positive, positive=>negative).

A “NOR Gate” combines a NOT and an OR gate to create one gate that returns positive if any of the inputs are positive, the NOR Gate then inverts the signal (i.e. negative=>positive, positive=>negative).

### BACKGROUND OF THE INVENTION

The Army says 80 percent of its aviation accidents are caused by human error—and that most of those are sparked by poor crew coordination. Poor crew coordination can led to a situation where neither pilot is in control of an aircraft.

The Apache carries two pilots, seated one behind the other, who routinely transfer control of the aircraft back and forth during a mission. Under Army guidelines, the pilots must go through a verbal handoff to ensure that control of the aircraft is properly transferred. Before handing off responsibility for flying the helicopter, the pilot who is flying is supposed to announce, “You have the controls,” to which the other responds, “I have the controls.” The pilot who initiated the transfer still is not supposed to transfer control until he announces once again, “You have the controls.”

The problem with this handoff procedure is that it relies on the hearing, clear communication of the message's intent and intended receiver, and remembrance of a communication and as a results of the repetitive routine, it is possible for one pilot to believe he has heard a confirmation that was not stated or after a period of time to become disoriented and believe that control was turned over, when it was not, both scenarios resulting in a period of time where no pilot is in control of the aircraft and there is no audio or visual warning system in the aircraft to confirm any state of control of the aircraft.

Given the instrumentation and electronics of modern aircraft, it is desirable that a system be developed to provide confirmation to the aircraft system and as well as audio and/or visual confirmation to both pilots as to whether someone is actively engaged in control of the aircraft and has their hands on the controls so that any situation where no pilot is in control of the aircraft is known to all crew members and can be resolved in the shortest amount of time.

What is needed is a positive, mechanical/electronic method of alerting pilots when no one has the controls.

### SUMMARY OF THE INVENTION

The Control Input Detection System, or CIDS, is a fully integrated flight control system. The direct purpose of the CIDS is to determine if the crewmember in the Pilot (aft) crew station and/or crewmember in the Co-Pilot Gunner (fore) crew station have/has their hands on the appropriate control surface. The indirect purpose is to ensure at least one pilot is actively involved in flying the aircraft at all times.

One of the aircraft's Electronic Load Centers routes a current to each crew station via the Input Analyzer, or IA. As the current routed through the IA reaches the respective crew station, it passes through the aluminum bands on each respective control surface. This current would return a control voltage to the cyclic voltmeter based on the minimal resistance of the ambient air in the crew station. When gloves (or hands) make contact with the aluminum bands, the resistance of the circuit is altered, returning a voltage to the respective control's voltmeter is different from the control voltage.

The IA will monitor the voltmeters' returns to determine at least one pilot has his hand(s) on the controls. If the control voltage were returned from all four voltmeters for longer than a predetermined amount of time, the IA would send a signal to the active System Processor, or SP1. The SP1 would then command the Display Processor, or DP, to send an audio tone to the Pilot and CPG's helmets, and an advisory to be displayed on the Enhanced Up-Front Display, or EUFD.

### BRIEF DESCRIPTION OF THE DRAWINGS

The accompanying drawings, which are incorporated herein an form a part of the specification, illustrate the present invention and, together with the description, further serve to explain the principles of the invention and to enable a person skilled in the pertinent art to make and use the invention.

FIG. 1 illustrates the system interaction flow chart of the present invention;

FIG. 2 is an electrical circuit representing the wiring needed to supplement an APACHE's current wiring system;

FIG. 3 illustrates the logic circuit of the present invention providing a visual representation of the CIDS' “thought process” during operation; and

FIGS. 4a-4c are sketches illustrating how the system would look when applied to the APACHE's controls, both cyclic and collective.

### DETAILED DESCRIPTION OF THE INVENTION

In the following detailed description of the invention of exemplary embodiments of the invention, reference is made to the accompanying drawings (where like numbers represent like elements), which form a part hereof, and in which is shown by way of illustration specific exemplary embodiments in which the invention may be practiced. These embodiments are described in sufficient detail to enable those skilled in the art to practice the invention, but other embodiments may be utilized and logical, mechanical, electrical, and other changes may be made without departing from the scope of the present invention. The following detailed description is, therefore, not to be taken in a limiting sense, and the scope of the present invention is defined only by the appended claims.

In the following description, numerous specific details are set forth to provide a thorough understanding of the invention. However, it is understood that the invention may be practiced without these specific details. In other instances, well-known structures and techniques known to one of ordinary skill in the art have not been shown in detail in order not to obscure the invention. Referring to the figures, it is possible to see the various major elements constituting the apparatus of the present invention.

The Control Input Detection System, or CIDS, is a fully integrated flight control system designed for the BOEING AH-64D APACHE LONGBOW, AH-64E APACHE GUARDIAN, and any successor models of the AH-64 APACHE. While the specifics of the flow chart and invention description would be unique to the APACHE family, the present invention can be applied to any tandem seat helicopter or aircraft, like the EUROCOPTER TIGER, BELL SUPERCOBRA/VIPER, etc.

The direct purpose of the CIDS 100 is to determine if the crewmember in the Pilot (aft) crew station 103 and/or crewmember in the Co-Pilot Gunner (fore) crew station 104 have/has their hands on the appropriate control surface 105, 106, 107, 108. The indirect purpose is to ensure at least one pilot is actively involved in flying the aircraft at all times.

One of the aircraft's Electronic Load Centers (ELCs) 101 routes a current to each crew station 103 and 104 via the Input Analyzer, or IA 102. Multiple aluminum bands are integrated into the collective flight controls 109 and 110 on both the Mission (fore) 105 and 107 and Flight (aft) grips 106 and 108, as well as the Cyclic grip 113 and 114. Flush with the circumference of the control surface, the system would react to contact of the Pilot's and Co-Pilot Gunner's (CPG) gloves. As the current routed through the IA 102 reaches the respective crew station 103 and 104, it passes through the aluminum bands on each respective control surface 105, 106, 107, and 108. This current would return a control voltage to the collective voltmeter 111 and 112 based on the minimal resistance of the ambient air in the crew station. When gloves (or hands) make contact with the aluminum bands, the resistance of the circuit is altered, returning a voltage to the respective control's voltmeter different from the control voltage.

The IA 102 will monitor the cyclic voltmeters' 115 and 116 returns to determine if at least one pilot has his/her hand(s) on the controls. If the control voltage were returned from all four voltmeters for longer than a predetermined amount of time, the IA 102 would send a signal to the active System Processor, or SP1 117. The SP1 117 would then command the Display Processor, or DP 118, to send an audio tone to the Pilot and CPG's helmets 119, and an advisory to be displayed on the Enhanced Up-Front Display, or EUFD 120.

The predetermined amount of time mentioned above would be chosen on a CIDS option page accessed via the Aircraft Utility page on the Multi-Purpose Display, or MPD 121. This page would also provide both crewmembers the option to be warned by audio tone. The EUFD 120 advisory would not be optional.

The IA 102 would perform a Built-In Test, or BIT, upon Auxiliary Power Unit, or APU start. The BIT would be similar to other aircraft systems in that the IA 102 would determine full functionality or any faults in the system. Faults would be listed on the Aircraft FAULT page. The BIT would also command the IA 102 to determine the control voltage explained above. The aircraft's Rearm/Refuel selection would be altered to include placing the CIDS 100 in STANDBY, during which no current would run through the circuit, minimizing an already infinitesimally minute risk of igniting fuel vapors during refueling operations.

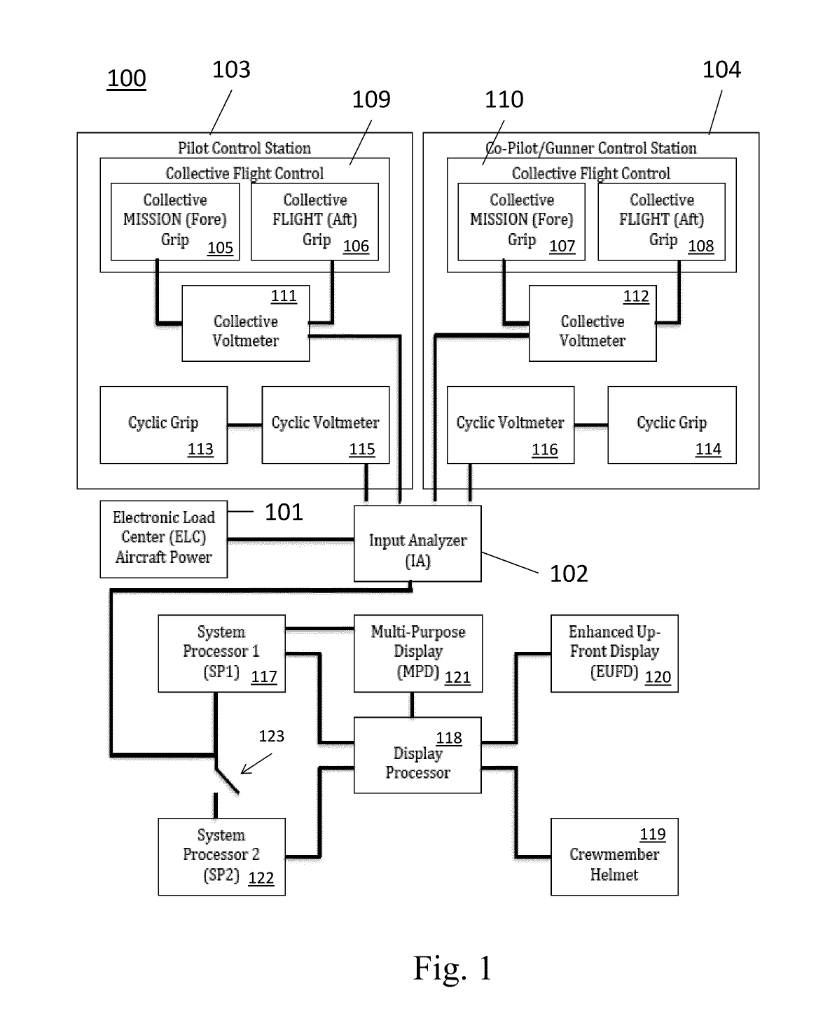

Now referring to FIG. 1, the embodiment of the Control Input Detection System 100, or CIDS is shown. The pilot control station 103 is comprised of a collective flight control 109, further comprised of a collective mission (fore) grip 105 and collective flight (aft) grip 106 which are connected to a collective voltmeter 111. The collective voltmeter 111, cyclic grip 113 and cyclic voltmeter 115 make up the remainder of the pilot control station in combination with the collective flight control 109 and interact directly with the input analyzer (IA) 102.

The co-pilot/gunner control station 104 is comprised of a collective flight control 110, further comprised of a collective mission (fore) grip 107 and collective flight (aft) grip 108, which are connected to a collective voltmeter 112. The collective voltmeter 112, cyclic grip 108, and cyclic voltmeter 116 make up the remainder of the co-pilot/gunner control station 104 in combination with the collective flight control 110 and interactive directly with the input analyzer (IA) 102.

The input analyzer (IA) 102 receives input from the collective voltmeters 111 and 112, cyclic voltmeters 115 and 116, or the pilot control station 103, the co-pilot/gunner control station 104, and the electronic load center (ELC) 101 for aircraft power.

The output of the input analyzer (IA) 102 is sent through a first system processor (SP1) 117 and a second system processor (SP2) 122. A switch 123 is located between the System Processors 117 and 122, placing the switch between the System Processor and the Display processor. Information is always supplied to both SP's 117 and 122 simultaneously. When necessary, the aircraft begins to take commands from SP2 122, for example when there is a problem with SP1 117.

A display processor 118 distributes a visual and/or audio alert to the multi-purpose display (MPD) 121, Enhanced Up-Front Display (EUFD) 120, and crew member helmet 119.

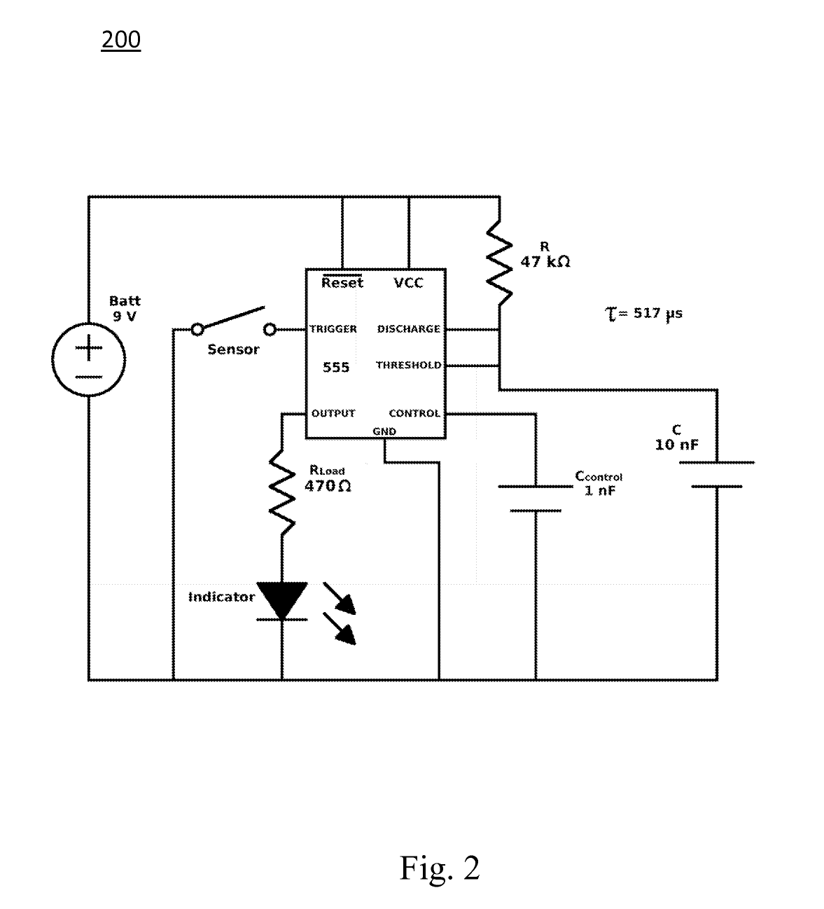

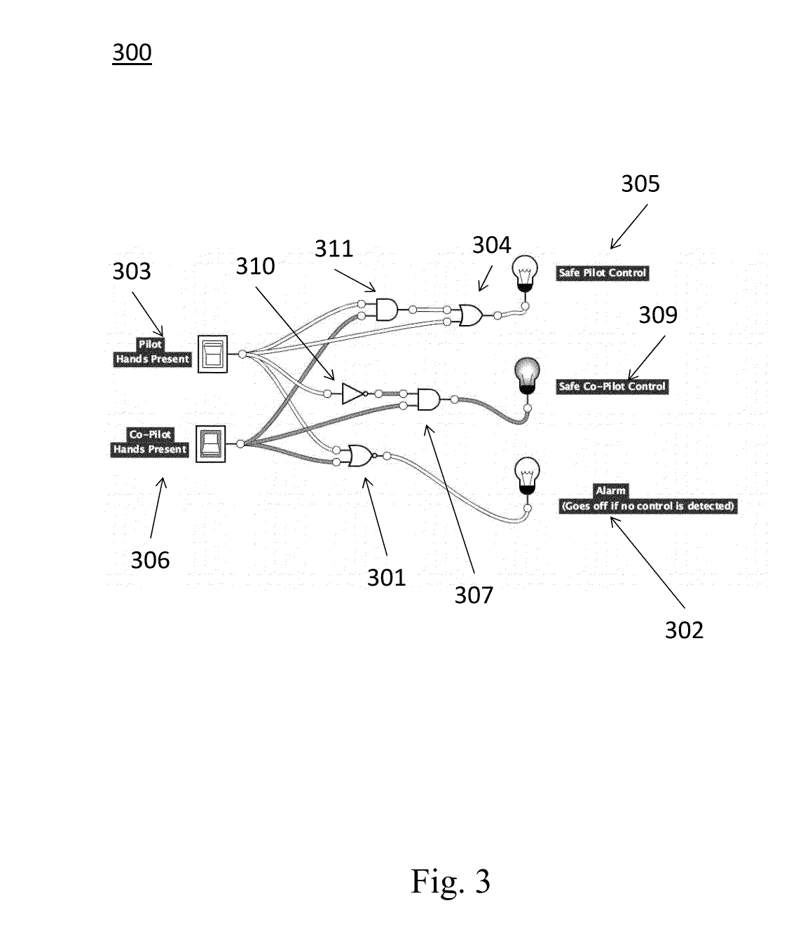

Now referring to FIG. 2, the logic circuit 200 of the present invention is illustrated. This circuit represents the logic behind the dual control system taught by the present invention, and controls when alarms would be triggered to pilots, and who should be in control of the aircraft at any one moment. There are four possible input combinations that each has its own output case, which are illustrated by the electrical circuit 300 representing the wiring needed to supplement an APACHE's current wiring system shown in FIG. 3.

In the first possible input combination, there are no hands present on the controls. In this case the lack of a signal, or rather a “False” value is passed down to the bottom NOR gate 301, which reverses the signal to a positive. With the now positive signal, the warning/alarm will sound 302.

In a second possible input combination, the pilot's hands are present on the controls 303. When only the pilots hands are present on the controls 303. A positive signal is sent through the top right OR gate 304 and signals that the pilot is in control. The positive signal from the Pilots controls keeps the alarm from firing 305.

In a third possible input combination, the Co-Pilot hands are present on the controls 306. When only the Co-Pilots hands are present on the controls 306, as shown in FIG. 3, the positive signal from the Co-Pilots controls are passed through the AND gate 307 along with the, now positive, inverted signal from the Pilots control 303 that passed through the NOT gate 310, thus signaling that the Co-Pilot is in control. The positive signal from the Co-Pilots controls keeps the alarm from firing 309.

In a fourth possible input combination, both the Pilot and Co-Pilot hands are present on the controls. When both sets of hands are present positive signals will be passed first to the top AND gate 311, and is then passed through the OR gate 304. This signals that the Pilot is in control. The positive signals from the Pilot and Co-Pilot keep the alarm from firing 305.

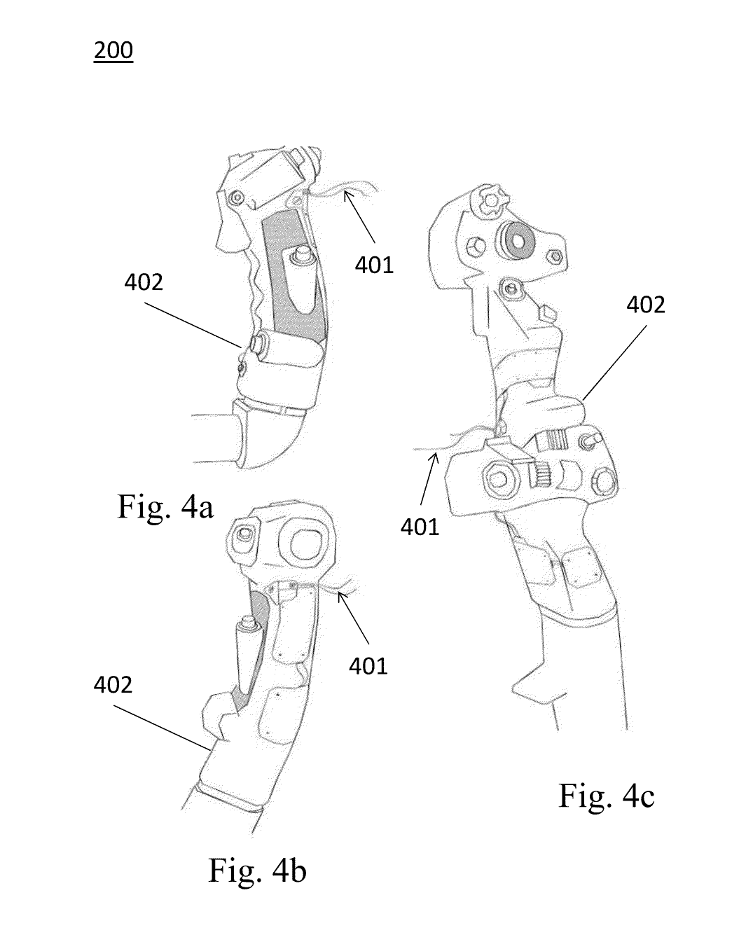

Finally, referring to FIGS. 4a-4c, these sketches illustrating how the system 401 would look when applied to the APACHE's controls 402, both in a cyclic and collective manner.

Thus, it is appreciated that the optimum dimensional relationships for the parts of the invention, to include variation in size, materials, shape, form, function, and manner of operation, assembly and use, are deemed readily apparent and obvious to one of ordinary skill in the art, and all equivalent relationships to those illustrated in the drawings and described in the above description are intended to be encompassed by the present invention.

Furthermore, other areas of art may benefit from this method and adjustments to the design are anticipated. Thus, the scope of the invention should be determined by the appended claims and their legal equivalents, rather than by the examples given.

The embodiments of the invention in which an exclusive property or privilege is claimed are defined as follows:

1. A Control Input Detection System comprising:
an Electronic Load Centers routing a current to each crew station via an Input Analyzer;
multiple aluminum bands are integrated into the collective on both the Mission (fore) and Flight (aft) grips, as well as the Cyclic grip, flush with the circumference of the control surface;
as the current is routed through the IA reaches the respective crew station, it passes through the aluminum bands on each respective control surface;
the current returns a control voltage to the voltmeter based on the minimal resistance of the ambient air in the crew station;
when the resistance of the circuit is altered, a returning a voltage to the respective control's voltmeter different from the control voltage;
the IA will monitor the voltmeters' returns to determine at least one pilot has his hand(s) on the controls;
if the control voltage were returned from all four voltmeters for longer than a predetermined amount of time, the IA would send a signal to the active System Processor, or SP; and
the SP would then command the Display Processor, or DP, to send an audio tone to the Pilot and CPG's helmets, and an advisory to be displayed on the Enhanced Up-Front Display, or EUFD.

2. The system of claim 1, wherein the predetermined amount of time mentioned would be chosen on a CIDS option page accessed via the Aircraft Utility page on the Multi-Purpose Display, or MPD.

3. The system of claim 1, wherein
the IA performs a Built-In Test, or BIT, upon Auxiliary Power Unit, or APU start;
the BIT would also commands the IA to determine the control voltage.

4. The system of claim 1, wherein the aircraft's Rearm/Refuel selection would be altered to include placing the CIDS in STANDBY.

5. The system of claim 1, wherein when there are no hands present on the controls,
a lack of a signal, or rather a “False” value is passed down to a bottom NOR gate, which reverses the signal to a positive; and
with the now positive signal, the warning/alarm will sound.

6. The system of claim 1, wherein when the pilot's hands are present on the controls,
a positive signal is sent through an OR gate and signals that the pilot is in control; and
the positive signal from the Pilots controls keeps the alarm from firing.

7. The system of claim 1, wherein when the Co-Pilot hands are present on the controls,
a positive signal from the Co-Pilots controls are passed through an AND gate along with the, now positive, inverted signal from the Pilots control that passed through the NOT gate, thus signaling that the Co-Pilot is in control; and
the positive signal from the Co-Pilots controls keeps the alarm from firing.

8. The system of claim 1, wherein when both the Pilot and Co-Pilot hands are present on the controls,
two positive signals will be passed first to the AND gate, and then passed through the OR gate;
this signals that the Pilot is in control; and
the positive signals from the Pilot and Co-Pilot keep the alarm from firing.

9. A method for providing Control Input Detection System for a helicopter:
accessing a factory wiring of a helicopter;
affixing multiple aluminum bands are integrated into the collective on both the Mission (fore) and Flight (aft) grips, as well as the Cyclic grip, flush with the circumference of the control surface;
routing an Electronic Load Centers current to each crew station via an Input Analyzer;
passing the current routed through the IA and the respective crew stations through the aluminum bands on each respective control surface;
returning a control voltage to the voltmeter based on the minimal resistance of the ambient air in the crew station;
returning a voltage to the respective control's voltmeter different from the control voltage when the resistance of the circuit is altered;
monitoring the voltmeters' returns by the IA to determine if at least one pilot has his hand(s) on the controls;
returning control voltage from all four voltmeters for longer than a predetermined amount of time, sending a signal to the active System Processor, or SP by the IA;
commanding the Display Processor, or DP, to send an audio tone to the Pilot and CPG's helmets; and
displaying an advisory on the Enhanced Up-Front Display, or EUFD.

10. The method of claim 9, wherein the predetermined amount of time mentioned would be chosen on a CIDS option page accessed via the Aircraft Utility page on the Multi-Purpose Display, or MPD.

11. The method of claim 9, further comprising the steps of
performing a Built-In Test, or BIT, upon Auxiliary Power Unit, or APU start; by the IA
commanding the IA to determine the control voltage by the BIT.

12. The method of claim 9, further comprising the step of
altering the aircraft's Rearm/Refuel selection to include placing the CIDS in a standby mode.

13. The method of claim 9, further comprising the steps of
passing down lack of a signal, or rather a “False” value down to a bottom NOR gate, which reverses the signal to a positive; and
sounding the warning/alarm in response to the positive signal.

14. The method of claim 9, further comprising the steps of
sending a positive signal through an OR gate and signaling that the pilot is in control; and
keeping the alarm from firing by the positive signal from the Pilots controls.

15. The system of claim 9, further comprising the steps of
passing a positive signal from the Co-Pilots controls through an AND gate along with the, now positive, inverted signal from the Pilots control that passed through the NOT gate;
signaling that the Co-Pilot is in control; and
keeping the alarm from firing by the positive signal from the Co-Pilots controls.

16. The system of claim 14,
passing two positive signals first to the AND gate, and then through the OR gate;
signaling that the Pilot is in control; and
keeping the alarm from firing by the positive signals from the Pilot and Co-Pilot.
